(19) United States
(12) Patent Application Publication
(10) Pub. No.: US 2023/0335496 A1
(43) Pub. Date: Oct. 19, 2023

(54) Process for Fabricating a 3D-NAND Flash Memory

(71) Applicant: MacDermid Enthone Inc., Waterbury, CT (US)

(72) Inventors: Frédéric RAYNAL, Paris (FR); Vincent MEVELLEC, Begles (FR); Mikailou THIAM, L'HAY-LES-ROSES (FR); Amine LAKHDARI, Montreuil (FR)

(21) Appl. No.: 18/030,158

(22) PCT Filed: Oct. 8, 2021
(86) PCT No.: PCT/EP2021/077913

§ 371 Date: Apr. 4, 2023

(30) Foreign Application Priority Data
Oct. 9, 2020 (FR) 2010350

(51) Int. Cl. H01L 23/532; H01L 21/768; H10B 43/27

(52) U.S. Cl. CPC H01L 23/53238; H01L 21/76843; H01L 21/76877; H10B 43/27

(57) ABSTRACT

The invention relates to a process for fabricating a 3D-NAND flash memory comprising a first step of electrodepositing an alloy of copper and of a dopant metal selected from manganese and zinc followed by a second step of annealing the alloy to form a first layer of copper and a second layer comprising zinc or manganese, by demixing the alloy.

### TECHNICAL FIELD

The present invention relates to the field of three-dimensional NAND flash memory devices and a process for creating copper conductor lines in such devices.

### PRIOR ART

3D-NAND flash memories are formed by a horizontal stack of alternating conductive metal layers (word lines, numbering a multiple of 8) and insulating layers. The conductor/insulator stack is pierced over its entire height by several vertical polysilicon semiconductor channels (drain) to create an array of three-dimensional memory cells, each cell being located at the intersection of a channel and a word line. The word lines are electrically connected to the bit lines and source lines. Contacts between the bit lines and the polysilicon drain are usually provided by tungsten pads or lines.

The conductivity and reliability of the metal contacts are very important criteria to provide good electron transfer in memories. However, the copper diffusion barrier materials that must be placed between the copper lines and the tungsten contact lines are highly resistive and block part of the current, which decreases the information transfer speed from the word lines to the bit lines, decreases the power supply from the copper source line to the word lines, and increases the battery consumption.

More precisely, the copper diffusion barrier layer between the tungsten and copper in current devices suffers from a number of disadvantages. The barrier materials used, such as tantalum nitride or titanium nitride, adhere poorly to copper, so a thin layer of tantalum or titanium is usually interposed between the nitride and the copper. On the other hand, since the tantalum layer is created by physical vapor deposition (PVD), it is necessary to cover it with a copper seed layer without breaking the vacuum in the chamber, to avoid its oxidation to tantalum pentaoxide, which is highly resistive.

The current process for creating copper lines in 3D-NAND flash memories is therefore complex, and it is desirable to provide a process that is much simpler to implement, involving fewer materials to be deposited at the interface between the tungsten contacts and the copper and, consequently, fewer fabricating steps.

There is also a need to provide a process for fabricating a 3D-NAND flash memory that reduces the electrical resistance between two metal levels and is easier to implement. The 3D-NAND flash memory fabricated according to this process is less expensive to fabricate, operates at a higher speed, and consumes less power.

Finally, the barrier layer deposited in the prior art by a dry process, for example in the vapor phase, does not have a uniform thickness over the entire covered surface, its thickness being higher on concave surfaces or on edges. Thus, in the particular case of the tungsten contacts placed between the polysilicon channels and the copper bit lines, a layer of tantalum nitride or titanium nitride deposited in the vapor phase, for example by CVD, will be thicker at the bottom of the copper-filled grooves, precisely at the point where the current flows. This difference in thickness of the barrier material between the bottom and the walls of the copper grooves, as well as the existence of overhangs at the edges of the grooves, results in a lower electrical resistance in certain areas impacting the reliability of the device, and an increased resistance in the current flow area.

To solve these problems, a thinner, it would be desirable to have a thinner, more conductive and compliant barrier to maximize the trench fill space, decrease the electrical resistance in the current flow areas, and increase the reliability of the 3D-NAND flash memory.

The present invention meets these various needs by at least partially replacing the barrier material used in the prior art, which is highly resistive and uneven in thickness, with a conformal, thinner and more conductive barrier layer.

The present invention also provides a process in which a copper diffusion barrier material and copper are deposited in grooves in a single filling step to create the copper bit lines.

Finally, the present invention makes it possible to selectively form a copper diffusion barrier layer substantially on insulating parts (most often in silicon dioxide) and to a lesser extent on the interface between copper and a metal contact, thus drastically decreasing the resistance between these two metal levels and, consequently, between the copper bit line and the contact connecting it to the polysilicon channel of the 3D-NAND flash memory.

### GENERAL DESCRIPTION

The invention meets to these various needs by proposing a process for fabricating a 3D-NAND flash memory wherein a copper diffusion barrier layer can be deposited on an insulating surface in a wet process step, and not in a dry process as in the prior art. The process of the invention makes it possible to deposit a dopant metal precursor to a copper diffusion barrier layer during the electrodeposition step of the copper to form the word lines. This step uses an electrolyte containing both copper ions and barrier material dopant metal precursor ions.

A dry process in the present description can a process selected from the group consisting of atomic layer deposition (ALD), physical vapor deposition (PVD) and chemical vapor deposition (CVD).

The invention provides a process comprising a first step of electrodepositing an alloy of copper and of a dopant metal selected from manganese and zinc, followed by a second step of annealing the alloy to cause it to demix and form a first layer of copper and a second layer comprising the dopant metal and/or an oxide thereof.

### BRIEF DESCRIPTION OF THE DRAWINGS

FIG. 1 shows a perspective drawing of a 3D-NAND flash memory of the prior art comprising a barrier material based on tantalum nitride or titanium nitride.

FIGS. 2A-2D show the steps of a process for fabricating the copper bit lines of a 3D-NAND flash memory according to the prior art.

FIGS. 3A-3C show a process for fabricating a 3D-NAND flash memory according to the invention in the “filling” mode.

FIGS. 4A-4D show a process for fabricating a 3D-NAND flash memory according to the invention in the “overburden” mode.

### DESCRIPTION OF THE EMBODIMENTS

Thus, the process of the invention is a process for fabricating a 3D-NAND flash memory, said process comprising a first step of electrodepositing an alloy of copper and of a dopant metal selected from manganese and zinc, said first electrodeposition step consisting in bringing the first surface of the metal layer into contact with an electrolyte comprising copper (II) ions and dopant metal ions, then polarizing said first surface for a time sufficient to cover it with the copper-dopant metal alloy, said first electrodeposition step being followed by a second step of annealing the alloy to cause it to demix and form a first layer of copper and a second layer comprising the dopant metal and/or an oxide thereof.

In particular, the first copper layer is intended to form a copper bit line of the 3D-NAND flash memory.

Advantageously, the electrolyte containing copper (II) ions and dopant metal ions has a pH comprised between 6.0 and 10.0, whereas the electrolytes of the prior art containing copper (II) ions used to form the copper bit lines have a much lower pH.

As used herein, “electrodeposition” is understood to mean any process in which a substrate is electrically polarized and brought into contact with a liquid containing metal precursors in order to deposit the metal on the surface of the substrate. Electrodeposition is performed by passing a current between the anode and the substrate to be coated, constituting the cathode, in an electrolyte containing metal ions.

According to an embodiment, a copper-manganese alloy or a copper-zinc alloy is deposited on a surface of a conductive metal layer, said conductive layer covering a dielectric material which is preferably an inorganic oxide. The alloy is then heat treated to separate the copper from the dopant metal to obtain a second layer comprising substantially manganese, zinc and/or an oxide thereof, and a first layer comprising substantially copper.

“Layer comprising substantially copper” means a copper deposit comprising less than 1% by mass of impurities, the impurities including any element except copper.

“Layer comprising substantially manganese, zinc and/or an oxide thereof” means a deposit comprising less than 1% by mass of impurities, the impurities including any compound except manganese, zinc and/or an oxide thereof.

During annealing of the alloy, the alloy demixes to form a thin layer comprising substantially manganese, zinc and/or an oxide thereof, and a layer of copper. This thin layer may then be interposed between the copper layer and a surface of a dielectric material. When the dielectric material is an inorganic oxide, it is possible for the atoms of the dopant metal to form an oxide from the oxygen atoms present in the dielectric and generate a layer having copper diffusion barrier properties, said layer comprising for example manganese oxide (MnO) or zinc oxide (ZnO).

The concentration of impurities in the copper deposit formed after annealing of the alloy may advantageously be less than 1% by mass. Moreover, the layers comprising substantially manganese, zinc and/or an oxide thereof fabricated according to the process of the invention have the advantage of being conformal (the variation in their thickness over their entire surface being preferably less than or equal to 10%). They are also very thin, for example ranging from 0.1 nm to 3 nm.

It is thus possible to obtain copper bit lines separated from a dielectric material by a thin and regular layer comprising substantially manganese, zinc and/or an oxide thereof. The process of the invention also makes it possible to considerably reduce the thickness of or even eliminate the copper diffusion barrier layer used in the prior art to separate the copper bit lines from the electrical contacts that connect them to the polysilicon channels.

According to a particular embodiment of the invention, the metal layer comprises a second surface which is in contact with a mixed surface comprising both an insulating area and a conducting area, said insulating area being made of a dielectric material, and said conducting area being made of a contact metal selected from tungsten, molybdenum, cobalt and ruthenium, said contact metal being intended to connect a copper bit line and a polysilicon channel of the 3D-NAND flash memory.

In particular, the dielectric material is selected from silicon dioxide, SiOC, SiOCH, SiN or SiC. According to a preferred embodiment, the dielectric material comprises oxygen. During the second step of annealing the alloy, the dopant metal migrates to the mixed surface, and the second layer comprising the dopant metal and/or an oxide thereof may thereby cover at least the insulating area of the mixed surface. In an advantageous embodiment, the second layer comprises an oxide of the dopant metal and performs the function of a copper diffusion barrier.

According to a first embodiment of the process of the invention, called “filling” mode, the metal layer is a metal seed layer consisting of copper, a copper alloy, or tantalum, said seed layer having been deposited in contact with the mixed surface of an insulating area and a conducting area, during a step prior to the first electrodeposition step. The first surface of the metal layer is in this case a surface of the seed layer and may be concave, defining a hollow delimited by the walls and the bottom of a trench. The trench hollow has, for example, an average width at the opening ranging from 15 nm to 700 nm and an average depth ranging from 30 nm to 500 nm. In this first embodiment of the process of the invention, the first step of electrodepositing the copper-dopant metal alloy can be performed for a time sufficient to fill the hollow with said alloy.

According to a second embodiment of the process of the invention, the metal layer is a trench-filling copper deposit, and the first step of electrodepositing the copper-dopant metal alloy is performed for a time sufficient to cover the trench-filling copper deposit, in order to form an alloy deposit, which may be termed “overburden”, the first copper layer formed as a result of the second annealing step being subsequently polished in a third chemical-mechanical polishing step. The trench-filling copper deposit may be formed by any method known to the person skilled in the art and preferably does not contain a dopant metal selected from manganese and zinc.

The first copper alloy electrodeposition step of the process of the invention may use, for example, an electrolyte comprising in solution in water:
copper (II) ions in a molar concentration comprised between 1 mM and 120 mM;
a copper ion complexing agent selected from aliphatic polyamines having from 2 to 4 amino groups, preferably ethylenediamine, in a molar concentration such that the ratio between the molar concentration of complexing agent and the molar concentration of copper ranges from 1:1 to 3:1;
ions of the metal selected from manganese and zinc in such a molar concentration that the ratio between the molar concentration of copper and the molar concentration of metal ranges from 1:10 to 10:1;
the electrolyte having a pH comprised between 6.0 and 10.0.

According to a particular embodiment, the electrolyte is obtainable by dissolving in water a copper (II) salt selected from copper sulfate, copper chloride, copper nitrate and copper acetate, preferably copper sulfate, and more preferably copper sulfate pentahydrate. The metal ions may be provided by dissolving an organic salt, preferably a carboxylic acid salt selected from gluconic acid, mucic acid, tartaric acid, citric acid and xylonic acid. The metal ions are preferably substantially complexed with the carboxylic acid or its carboxylate form in the electrolyte.

According to a particular feature, the copper ions are present within the electrodepositing composition in a concentration comprised between 1 mM and 120 mM, preferably between 10 mM and 100 mM, and more preferably between 40 mM and 90 mM.

The copper ion complexing agent consists of one or more compounds selected from aliphatic polyamines having from 2 to 4 amino groups (—NH2). Among the aliphatic polyamines that may be used, mention may be made of ethylenediamine, diethylenediamine, triethylenetetramine and dipropylenetriamine, preferably ethylenediamine.

The ratio between the molar concentration of complexing agent and the molar concentration of copper ions comprised between 1:1 and 3:1, preferably 1.5 and 2.5, and more preferably between 1.8 and 2.2.

In the electrolyte, the copper ions are substantially in the form of complexes with the complexing agent.

The metal ions are in such a molar concentration that the ratio between the molar concentration of copper and the molar concentration of the metal ranges from 1:10 to 10:1.

In a particular embodiment of the invention, the metal is zinc. In this case, the ratio between the molar concentration of copper ions and the molar concentration of zinc ions is preferably from 1:1 to 10:1.

When the metal is manganese, the ratio between the molar concentration of copper and the molar concentration of manganese can range from 1:10 to 10:1.

The pH of the electrolyte may be comprised between 6.0 and 10.0, more preferably between 6.5 and 10.0. According to a particular embodiment, the pH is comprised between 6.5 and 7.5, preferably between 6.8 and 7.2, for example equal to 7.0 at ready measurement uncertainties. The pH of the composition may optionally be adjusted to the desired range by means of one or more pH modifying compounds, such as tetra-alkylammonium salts, for example tetra-methylammonium or tetra-ethylammonium. Tetra-ethylammonium hydroxide may be used.

Although there is no restriction in principle on the nature of the solvent (provided that it sufficiently solubilizes the active species in the solution and does not interfere with the electrodeposition), it will preferably be water. According to an embodiment, the solvent comprises mostly water by volume.

According to a particular embodiment, the composition contains between 40 mM and 90 mM copper sulfate, ethylenediamine in a molar ratio with copper comprised between 1.8 and 2.2, and zinc gluconate in such a concentration that the ratio between the molar concentration of copper and the molar concentration of zinc ranges from 2:1 to 3:1. Its pH is preferably of the order of 7.

The first step of electrodepositing the alloy of copper and of the selected metal may comprise:
a step of bringing a conductive surface of the trenches into contact with an electrolyte according to the preceding description,
a step of polarizing the conductive surface for a time sufficient to achieve deposition of the alloy.

The manganese content or the zinc content in the alloy deposited at the conclusion of the first electrodeposition step is preferably comprised between 0.5 atomic % and 10 atomic %.

The polarization step is performed for a time sufficient to form the desired alloy thickness. The conductive surface can be polarized either in galvanostatic mode (fixed imposed current), or in potentiostatic mode (imposed and fixed potential, optionally in relation to a reference electrode), or in pulsed mode (in current or in voltage).

In a particular embodiment of the process for fabricating a 3D-NAND flash memory according to the invention, the copper-metal alloy is deposited on the surface of a copper layer. The copper layer may be a seed layer covering the bottom and wall of trenches that have been etched in a prior step, or a volume of copper that fills trenches and has been previously deposited according to a process known to the skilled person.

In a first embodiment, the alloy is deposited to fill cavities which have been previously dug in a substrate and whose surface has been covered with a layer of a dielectric material and then optionally with a layer of a metallic material, in particular a copper and/or tantalum seed layer (so-called “filling” mode). In this first embodiment, the alloy is deposited on the conductive surface of the trenches to be filled.

In a second embodiment, the alloy is deposited on a layer of copper that fills cavities opening onto the surface of a substrate (so-called “overburden” mode). The conductive surface then comprises a portion corresponding to the copper deposit that fills the cavities and a portion corresponding to the surface of the substrate onto which the cavities open.

The cavities may have an average width at the opening comprised between 15 nm and 700 nm and an average depth comprised between 100 nm and 500 nm.

In the first embodiment, the process in accordance with the invention has made it possible to achieve copper fillings of excellent quality, without material defects and does not generate contaminants in large amounts.

The surface of the cavities to be filled with the alloy is, for example, the first surface of a metal layer having a second surface which is in contact with a layer of a dielectric material, preferably an inorganic oxide such as silicon dioxide, usually deposited by CVD.

The seed layer is, for example, made of a single material such as copper or tantalum. Alternatively, the seed layer consists of an assembly of two layers including a copper layer and a so-called “liner” layer interposed between the copper layer and the dialectic material, which can improve the adhesion of the copper to the material. The liner can be made of tantalum, ruthenium, cobalt, titanium or an alloy thereof, for example.

In a particular embodiment, the metal layer is a seed layer consisting of copper having a thickness ranging from 4 nm to 20 nm, or a seed layer consisting of the assembly of a liner having a thickness of 1 nm and a seed layer of copper having a thickness of 5 nm.

According to the second embodiment, the filling of the cavities was carried out with pure copper by any method known to the skilled person, whether by physical deposition (PVD, CVD, ALD), or by wet process (autocatalytic or electrolytic). In the sense of the present invention, “pure copper” means copper containing no other metallic element, in particular copper free of zinc or manganese. In particular, “pure copper” in the sense of the present invention may be understood to mean a copper deposit advantageously containing less than 1 atomic % of elements other than copper. The impurities may in particular include oxygen, carbon and nitrogen.

The first electrodeposition step may comprise a single or multiple polarization steps, the variables of which skilled persons will know how to choose on the basis of their general knowledge, carried out at a temperature comprised between 20° C. and 30° C.

It can be performed using at least one polarization mode selected from the group consisting of the ramp mode, the galvanostatic mode and the galvanopulse mode.

According to an embodiment, the polarization of the conductive surface is performed in a pulsed mode by imposing a current per unit area comprised in the range of 3 mA/cm2 to 25 mA/cm2 at a frequency ranging from 5 kHz to 15 kHz, and by exerting zero current periods at a frequency ranging from 1 kHz to 10 kHz.

The conductive surface may be brought into contact with the electrolyte either before or after polarization. It is preferred that the contact is made before energization.

The first electrodeposition step is stopped when the alloy deposit covers the flat surface of the substrate to a thickness comprised between 50 nm and 400 nm, for example comprised between 125 nm and 300 nm. The alloy deposit corresponds either to the alloy mass deposited in the hollow volume of the cavities without filling them completely, or to the combination of the alloy mass filling the entire hollow volume of the cavities and the alloy mass covering the surface of the substrate, or only to the mass covering the surface of the substrate and the upper part of a copper deposit filling the cavities and which was produced in a step prior to the first electrodeposition step.

The deposition rate of the copper alloy can be in the range comprised between 0.1 nm/s and 6.0 nm/s, preferably between 1.0 nm/s and 3.0 nm/s, and more preferably between 1 nm/s and 2.5 nm/s.

The process of the invention comprises a second step of annealing the copper alloy deposit obtained at the conclusion of the first electrodeposition step.

This annealing heat treatment can be carried out at a temperature comprised between 50° C. and 550° C., preferably under reducing gas such as 4% H₂ in N₂.

A low impurity content combined with a very low percentage of voids results in a copper deposit with low resistivity.

During the annealing step, the manganese or zinc atoms separate from the copper, resulting in the formation of two layers: a first layer comprising substantially copper, and a second layer comprising substantially manganese, zinc and/or an oxide thereof.

The conductive surface with which the electrolyte is brought into contact may be the surface of a metal seed layer, which layer overlies an insulating dielectric material, itself overlying polysilicon. In this embodiment, the manganese or zinc atoms migrate during the annealing step through the seed layer to the interface between the seed layer and the dielectric insulating material.

The layer comprising substantially manganese, zinc and/or an oxide thereof is preferably a continuous and conformal layer with an average thickness ranging from 0.5 nm to 2 nm. “Continuous” means that the layer covers the entire surface of the dielectric substrate without leaving it flush. “Conformal” means a layer whose thickness preferably varies by ±10% with respect to its average thickness.

The total impurity content of the first copper layer obtained by the process of the invention at the conclusion of the second annealing step is advantageously less than 1 atomic %. The impurities include mainly oxygen, followed by carbon and nitrogen. The total carbon and nitrogen content is preferably less than 300 ppm.

The process of the invention may include a preliminary step of reducing plasma treatment so as to reduce the native metal oxide present on the surface of the metal layer. Preferably, the first electrodeposition step is performed immediately after the plasma treatment to minimize reformation of native oxide.

The process of the invention may also comprise a step of creating the metal contact of a contact metal selected from tungsten, molybdenum, cobalt and ruthenium, said contact creation step being prior to the deposition of the metal layer described above. This metal contact forming step may be performed by a method known to the skilled person.

The 3D-NAND device obtained using the process of the invention may comprise at least one copper diffusion barrier material placed between copper and an insulating material, said barrier material comprising zinc or manganese.

In the sense of the present invention, “3D-NAND flash memory” means a vertically integrated memory such as, for example, Bit-Cost Scalable® (BiCS) commercial reference memory, Pipe-shape Bit-Cost Scalable® (P-BiCS) commercial reference memory, Terabit Cell Array Transistor (TCAT) and Vertical NAND (V-NAND) memories.

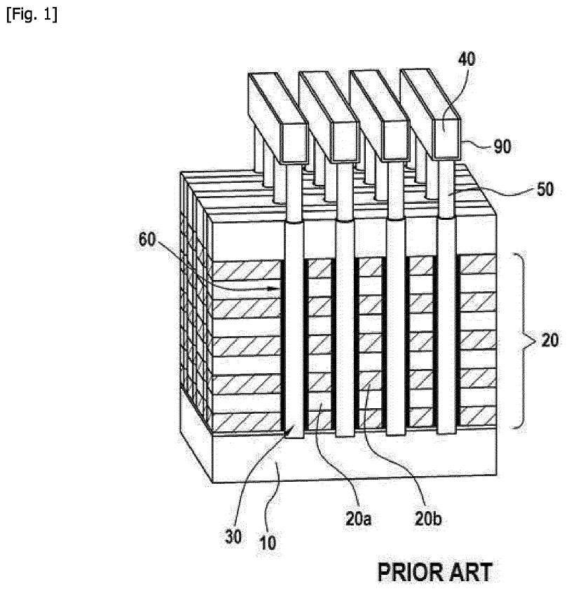

A 3D-NAND flash memory according to the prior art, reproduced in FIG. 1, may comprise
a silicon substrate 10 covered by a stack of layers 20 located in a horizontal plane, said stack alternating silicon dioxide layers 20a and conductive metal layers constituting word lines 20b,
at least one polysilicon channel 30 passing vertically through the stack of layers 20, and
at least one copper bit line 40 located in a plane parallel to the stack of layers and located above said stack,
the polysilicon channel 30 and the copper bit line 40 being electrically connected by a metal contact 50,
the polysilicon channel 30 and the word line 20b being separated by a charge storage area 60 generally comprising silicon nitride (ONO), and
the copper bit line 40 being separated from the metal contact 50 by a copper diffusion barrier material 90 generally comprising tantalum nitride or titanium nitride.

The invention consists in providing a method for at least partially replacing the copper diffusion barrier material 90 used in the prior art with another copper diffusion barrier material comprising zinc, manganese or an oxide thereof. This increases the electrical conductivity between the copper bit line 40 and the polysilicon channel. In particular, the process allows the barrier layer 90 of the prior art to be removed. In a particular embodiment, the process of the invention allows for the deposition of a layer comprising a zinc- or manganese-based material at least on the vertical walls, and optionally on the bottom of the copper bit lines, the nature of the deposited material being able to vary according to its location on the surface of the copper line. For example, the zinc- or manganese-based material deposited on the walls of the copper lines may have a copper diffusion barrier function. For example, no zinc- or manganese-based material will be deposited on the bottom of the copper lines so that the copper will be in contact with the metal contact. Finally, the zinc- or manganese-based material may be deposited on the bottom of the copper lines at the interface with the metal contact, without the layer providing a barrier function. All these options will depend on the chemical nature of the deposited zinc or manganese material. In particular, a zinc oxide or manganese oxide will act as a copper diffusion barrier when deposited to a sufficient thickness.

A 3D-NAND flash memory, a schematic of which is shown in FIG. 1, may be fabricated in the prior art by a method comprising two series of steps. In a first series of steps, the metal contact 50 is created on the upper part of the polysilicon channel 30, the metal contact 50 being generally made of molybdenum, tungsten, cobalt or ruthenium, most commonly tungsten. According to a particular process of the prior art, the first series of steps consisting in creating the metal contact comprises:
depositing a silicon dioxide layer by CVD on at least the upper part of the polysilicon channel 30, followed by etching the silicon dioxide by lithography to form at least one cavity,
successively depositing, on the surface of the cavity, a seed layer of titanium or tantalum, by PVD, and of a copper diffusion barrier layer, for example of titanium nitride or tantalum nitride, using a CVD method,
filling the cavity with tungsten by CVD, and chemical-mechanical polishing (CMP) of the excess tungsten deposited, to obtain the metal contact 50.

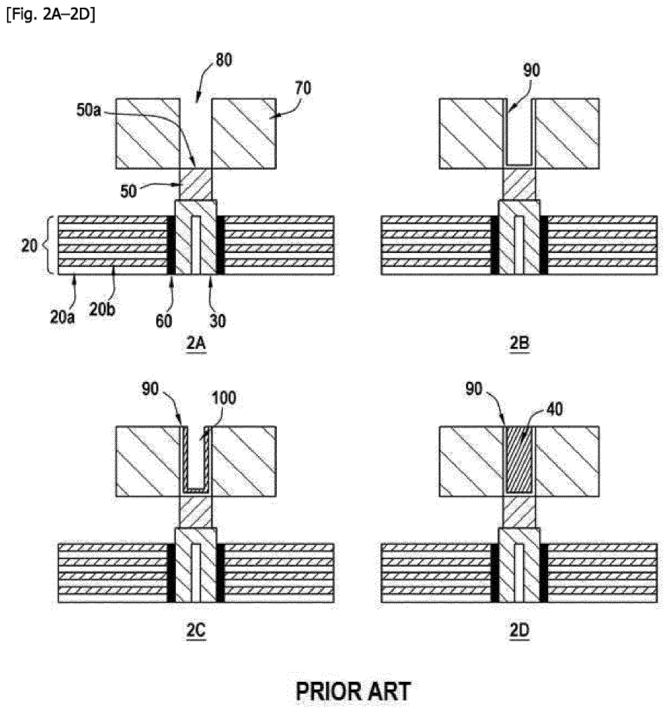

In a second series of steps of a process of the prior art partially shown in FIGS. 2A-2D, the copper bit line is deposited on the metal contact obtained from the first series of steps.

The second series of steps consisting in creating a copper bit line 40 on the metal contact 50 may comprise in particular:
a step of depositing—on the metal contact 50—a layer of silicon dioxide 70 by PECVD followed by a step of etching at least one trench 80 in said layer of silicon dioxide 70, said etching step leaving a surface of the metal contact 50a at the bottom of the trench 80 flush, as illustrated in FIG. 2A, and
a step of depositing—on the walls and bottom of the trench 80—a copper diffusion barrier layer 90 by PECVD, typically tantalum nitride, as illustrated in FIG. 2B,
a step of depositing a copper seed layer 100 by PECVD on the copper diffusion barrier layer 90, as shown in FIG. 2C, and then
a step of filling the remaining void volume in the trench with copper by electrodeposition, followed by a step of chemical-mechanical polishing of the excess deposited copper to form the copper bit line 40 shown in FIG. 2D.

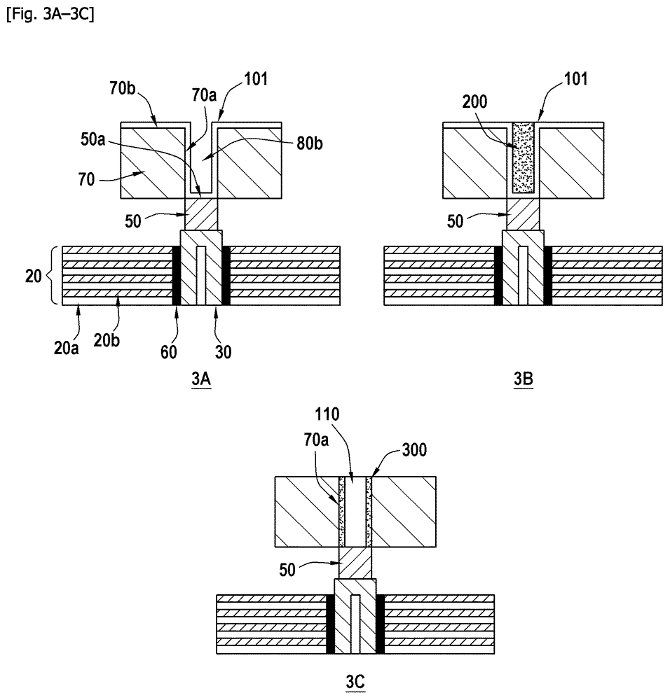

A particular example of the process for fabricating a 3D-NAND flash memory in accordance with the invention is shown in FIGS. 3A-3C. These figures illustrate the first variant of the process of the invention described above according to which the first step of electrodepositing the copper-dopant metal alloy leads to the complete filling of the volume of a trench.

In FIG. 3A, a substrate is provided comprising
a stack of layers 20 located in a horizontal plane, said stack alternating silicon dioxide layers 20a and conductive metal layers constituting word lines 20b,
at least one polysilicon channel 30 passing vertically through the stack of layers 20,
a metal contact 50 located on the upper part of the polysilicon channel 30, and a trench which has been cut into a dielectric layer 70, to create a mixed surface comprising a dielectric surface 70a on the walls of the trenches, a dielectric surface 70b outside the trenches, and a surface of the metal contact 50a. Said mixed surface is covered with a thin metal layer 101 so as to leave a void volume in the trench 80b.

As illustrated in FIG. 3B, an alloy of copper and of a dopant metal selected from manganese and zinc 200 was electrodeposited on the metal seed layer 101 at the conclusion of a first electrodeposition step in accordance with the process of the invention, to fill the volume 80b.

In FIG. 3C, the copper and dopant metal have been separated by annealing the alloy 200 according to the second step of the process of the invention to form a first layer of copper 110 filling the trench, and a second layer comprising the dopant metal and/or an oxide thereof 300 located at the interface between the dielectric surface 70a and the first layer of copper 110.

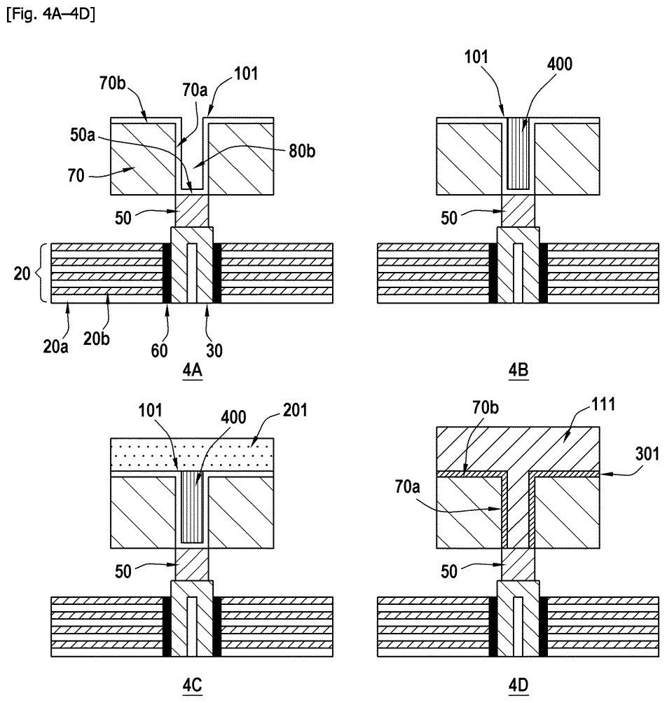

FIGS. 4A-4C illustrate the second variant of the process of the invention described above, according to which the first step of electrodepositing the copper-dopant metal alloy is carried out after filling the volume of the trench 80b with copper according to a process of the prior art. In this variant, a prior pure-copper filling step consists in filling the trench with copper, for example by electrodeposition, and then depositing the copper-metal alloy—on the trench-filled copper-in accordance with the first electrodeposition step described above to form a copper-dopant metal alloy deposit referred to as “overburden”.

A substrate is provided conforming to that shown in FIG. 4A and identical to that shown in FIG. 3A comprising in particular a metal seed layer 101 and a void volume 80b in the trench.

As illustrated in FIG. 4B, this void volume 80b was filled with a copper deposit 400 by a method known to the skilled person, for example by electrodeposition using an electrolyte containing copper (II) ions identical to or different from the electrolyte used in the first electrodeposition step further containing a dopant metal ion, preferably an electrolyte containing metal ions which are all copper (II) ions.

In FIG. 4C, an alloy of copper and of the dopant metal 201 is deposited on the copper deposit 400, at the conclusion of the first electrodeposition step in accordance with the process of the invention.

The alloy 201 is then annealed in a second step of annealing the alloy in accordance with the process of the invention to cause it to demix and form a first layer of copper 111 as shown in FIG. 4D which comprises the volume of copper that was contained in the seed layer 101 and the volume of copper that was part of the alloy 201. The annealing also allows for the formation of a second layer comprising the dopant metal and/or an oxide thereof 301, located at the interface between a dielectric surface (comprising the dielectric surface 70a and the dielectric surface 70b), and the first copper layer 111. The second layer comprising the dopant metal and/or an oxide thereof may or may not cover the surface 50a of the metal contact 50. In FIG. 4D, the dielectric 70 silicon dioxide, and the second layer comprising the dopant metal 301 comprises zinc oxide or manganese oxide and does not cover the surface of the metal contact 50a.

The process of the invention is advantageously intended for the creation of copper bit lines to fabricate a 3D-NAND device and may comprise, prior to the first electrodeposition step, a step of creating polysilicon channels, a step of creating word lines, and a step of creating metal contacts, said steps being carried out according to methods known to the skilled person. According to an advantageous embodiment of the process of the invention, at least one step of depositing a copper diffusion barrier material which is performed by dry process in the prior art is replaced by a step of depositing an alloy of copper and of a dopant metal selected from zinc or manganese, the deposition step being in accordance with the first electrodeposition step described above.

The process of the invention may comprise, prior to the first step of electrodepositing the copper-metal alloy,
a step of depositing a layer of silicon dioxide, followed by
a step of etching this layer to form at least one cavity having a side wall made of silicon dioxide and a bottom made of metal contact material,
a step of depositing on the wall and the bottom of the cavity a metal seed layer consisting of copper or of the assembly of a metallic adhesion layer (known as a “liner”) and a copper layer.

Another subject matter of the invention is the use of zinc or manganese in a process for fabricating a 3D-NAND flash memory, in order to suppress the intercalation of a copper diffusion barrier material (generally highly resistive), between a metal contact and a copper bit line, said barrier material being deposited by dry process and being selected for example from tantalum nitride and titanium nitride, said metal contact electrically connecting a polysilicon channel and said copper bit line in the 3D-NAND flash memory, and comprising a contact metal selected from tungsten, molybdenum, cobalt and ruthenium.

The invention is illustrated by the following examples.

### Example 1: Electrodepositing and Annealing a Copper-Zinc Alloy to Fill Cavities Covered with a Tantalum/Copper Seed Layer, and Overhanging a Tungsten Contact

Trenches 300 nm wide and 600 nm deep were filled with a copper-zinc alloy by electrodeposition on a tantalum/copper seed layer. The deposition is done using a pH 7 composition containing a sulfur salt of copper (II) ions and an organic salt of zinc (II) ions in the presence of ethylene diamine.

A.—Materials and Equipment:

### Substrate:

The substrate used in this example consisted of a 4×4 cm silicon coupon on which 300 nm wide and 600 nm deep trenches are etched. On the side walls, the silicon is covered with silicon oxide which is also covered with a thin layer of tantalum 1 nm thick and in contact with a layer of copper metal 5 nm thick. While on the bottom of the trench, the silicon is covered with a thick layer of tungsten and in contact with a 5 nm thick layer of copper metal. The measured resistivity of the substrate is about 30 ohm/square.

### Electrodeposition Solution:

In this solution, copper is provided by 16 g/L CuSO₄(H₂O)₅ (64 mM Cu²⁺) with two molar equivalents of ethylene diamine. Zinc is supplied by zinc gluconate to give 25 mM Zn²⁺. Tetraethylammonium hydroxide (TEAH) is added to adjust the pH of the solution to 7.

### Equipment:

In this example, an electrodeposition apparatus was used consisting of two parts: the cell to hold the electrodeposition solution equipped with a fluid recirculation system to control the hydrodynamics of the system, and a rotating electrode equipped with a sample holder suitable for the size of the coupons used (4 cm×4 cm). The electrodeposition cell had two electrodes: a copper anode, and the silicon coupon coated with the copper metal layer constitutes the cathode. The reference was connected to the anode. Connectors allowed electrical contact of the electrodes which were connected by electrical wires to a potentiostat providing up to 20 V or 2 A.

B.—Experimental Protocol:

### Preliminary Step:

The substrates do not generally require any particular treatment except if the native copper oxide layer is too important due to an advanced age of the wafers or a bad storage of the latter. This storage is normally done under nitrogen. In this case it is necessary to perform a plasma containing hydrogen. Either pure hydrogen or a gas mixture containing 4% hydrogen in nitrogen.

### First Step of Electrodeposition:

The cathode was polarized in galvanopulse mode in a current range of 10 mA (or 1.4 mA/cm2) to 200 mA (or 28.6 mA/cm2), for example 150 mA (or 21.4 mA/cm2) with a pulse duration comprised between 5 and 1000 ms in cathodic polarization, and between 5 and 1000 ms in zero polarization between two cathodic pulses. This step was carried out under a rotation of 60 rpm for 5 minutes.

### Second Step of Annealing:

Annealing is performed at a temperature of 100° C. under hydrogen atmosphere (4% hydrogen in nitrogen) for 30 minutes and then 350° C. for 15 min, so as to cause the migration of zinc on the side walls of the trenches which is the interface between SiO₂ and copper.

C—Results Obtained:

A transmission electron microscopy (TEM) analysis, carried out after annealing, reveals a flawless filling of holes on the walls of the trenches reflecting good copper nucleation and no holes in the structures. The copper layer thickness on the structures is 200 nm. XPS analysis before annealing shows the presence of zinc in the alloy of the order of 2 atomic %, uniformly. The same type of analysis, after annealing, shows on the one hand the migration of zinc both toward the SiO₂—Ta interface and toward the extreme surface but not toward the W-copper interface. On the other hand, the total contamination in oxygen, carbon and nitrogen does not exceed 600 atomic ppm. This integration has the advantage of reducing the line resistances and thus optimizing the memories.

### Example 2: Electrodepositing and Annealing of a Copper-Zinc Alloy for Filling Cavities Covered with a Copper Seed Layer, and Overhanging a Tungsten Contact

Trenches 300 nm wide and 600 nm deep were filled with a copper-zinc alloy by electrodeposition on a copper seed layer deposited directly on SiO2. The deposition is done using a pH 7 composition containing a sulfur salt of copper (II) ions and an organic salt of zinc (II) ions in the presence of ethylene diamine.

A.—Materials and Equipment:

### Substrate:

The substrate used in this example consisted of a 4×4 cm silicon coupon on which 300 nm wide and 600 nm deep trenches are etched. On the side walls, the silicon is covered with silicon oxide which is also in direct contact with a layer of copper metal 5 nm thick. While on the bottom of the trench, the silicon is covered with a thick layer of tungsten and in contact with a 5 nm thick layer of copper metal. The measured resistivity of the substrate is about 30 ohm/square.

### Electrodeposition Solution:

The electrodeposition solution used is the same as in Example 1.

### Equipment:

The equipment used is the same as in Example 1.

B.—Experimental Protocol:

### Preliminary Step:

The substrate does not require any special treatment.

### First Step of Alloy Electrodeposition:

It is identical to that of Example 1.

### Second Step of Annealing:

The annealing is the same as in Example 1.

C—Results Obtained:

A transmission electron microscopy (TEM) analysis, carried out after annealing, reveals a flawless filling of holes on the walls of the trenches reflecting good copper nucleation and no holes in the structures. The copper layer thickness on the structures is 200 nm. XPS analysis before annealing shows the presence of zinc in the alloy of the order of 2 atomic %, uniformly. The same type of analysis, after annealing, shows a more significant migration of zinc toward the SiO₂—Cu interface than in Example 1. This integration is optimal for reducing line resistances and thus optimizing memories.

### Example 3: Filling Structures with Copper Followed by Electrodeposition and Annealing of a Copper-Zinc Alloy to Achieve a 300 nm so-Called “Overburden” Deposit Overhanging a Tungsten Contact

Trenches 300 nm wide and 600 nm deep were filled with copper by electrodeposition on a copper seed layer. The deposition is done with a pH 7 composition containing a sulfur salt of copper (II) ions of ethylenediamine and thiodiglycolic acid.
Next, a 300 nm thick copper-zinc alloy overburden is electrodeposited onto the copper deposited in the first step. The overburden is made with a pH 7 composition containing a sulfur salt of copper (II) ions and an organic salt of zinc (II) ions in the presence of ethylene diamine.

### A.—Materials and Equipment:

### Substrate:

The substrate used is the same as Example 2.

### Electrodeposition Solutions:

First solution of copper: in this solution, copper is provided by 16 g/L CuSO₄(H₂O)₅ (64 mM Cu²⁺) with two molar equivalents of ethylene diamine and 50 ppm thiodiglycolic acid for trench filling. TEAH is added to adjust the pH of the solution to 7.
Second solution of copper and zinc for overburden: copper is provided by 16 g/L
CuSO₄(H₂O)₅ (64 mM Cu²⁺) with two molar equivalents of ethylene diamine. Zinc is provided by Zn Gluconate to obtain 25 mM Zn²⁺. TEAH is added to adjust the pH of the solution to 7.

### Equipment:

The equipment used is the same as in Example 1.

### B.— Experimental Protocol:

### Preliminary Step:

The substrate does not require any special treatment.

### 1—Copper Filling

The process is performed as follows: the cathode was polarized in ramp mode in a current range from 20 mA (or 1.4 mA/cm2) to 120 mA (or 17.1 mA/cm2). For example, a current ramp ranging from 20 mA (or 2.9 mA/cm2) to 100 mA (or 14.3 mA/cm2) with a slope comprised between 0.5 and 2 mA/s.

### 2—First Electrolytic Step of Depositing the Alloy to Form an Overburden

The conditions are identical to those of Example 1.

### 3—Second Step of Annealing:

The annealing is the same as in Example 1.

### C—Results Obtained:

A transmission electron microscopy (TEM) analysis, carried out after annealing, reveals a flawless filling of holes on the walls of the trenches reflecting good copper nucleation and no holes in the structures. The copper layer thickness on the structures is 300 nm. XPS analysis before annealing shows the presence of zinc in the alloy in the order of 2 atomic %, uniformly in the thick copper layer. While in the structures, the copper is pure. The same type of analysis, after annealing, shows on the one hand the migration of zinc through the pure copper to reach the SiO₂—Cu interface and toward the extreme surface. On the other hand, the total contamination in oxygen, carbon and nitrogen does not exceed 600 atomic ppm. This solution has the advantage of working on thinner trenches.

### Example 4: Electroplating and Annealing of a Copper and Zinc Alloy for Filling Cavities Covered with a Copper Seed Layer, and Overhanging a Nickel-Boron Contact

Trenches 300 nm wide and 600 nm deep were filled with an alloy of copper and zinc by electrodeposition on a copper seed layer deposited directly on SiO2. The deposition is carried out using a composition at pH 7 containing a sulfur salt of copper (II) ions and an organic salt of zinc (II) ions in the presence of ethylene diamine.

### A.—Materials and Equipment:

### Substrate:

The substrate used in this example consisted of a silicon coupon 4×4 cm on which are etched trenches 300 nm wide and 600 nm deep. On the side walls, the silicon is coated with silicon oxide which is also in direct contact with a layer of metallic copper with a thickness of 5 nm. While on the bottom of the trench, the silicon is covered with a thick layer of NiB and in contact with a layer of metallic copper with a thickness of 5 nm. The measured resistivity of the substrate is approximately 30 ohm/square.

### Electrodeposition Solution:

The electroplating solution used is the same as in Example 1.

### Equipment:

The equipment used is the same as in Example 1.

### B.—Experimental Protocol:

### Preliminary Step:

The substrate does not require any special treatment.

### 1—First Electrolytic Step

The conditions are identical to those of Example 1.

### 2—Second Step of Annealing:

The annealing is the same as in Example 1.

### C—Results Obtained:

Transmission electron microscopy (TEM) analysis, carried out after annealing, reveals a flawless filling of holes on the walls of the trenches indicating good nucleation of the copper and no holes in the structures. The thick layer of copper on the structures is 200 nm. An XPS analysis before annealing shows the presence of zinc in the alloy of the order of 2 atomic %, to have. This same type of analysis, after annealing, shows a migration of zinc to the SiO2-Cu interface and not to the NiB—Cu interface.

### Example 5: Filling of Structures with Copper Followed by Electroplating and Annealing of a Copper and Zinc Alloy to Produce a so-Called “Overburden” Deposit of 300 nm Overhanging a Nickel-Boron Contact

Trenches 300 nm wide and 600 nm deep were filled with copper by electrodeposition on a copper seed layer. The deposition is made using a composition at pH 7 containing a copper (II) ion sulfur salt of ethylenediamine and thiodiglycolic acid.
Next, an overburden of a copper-zinc alloy 300 nm thick is electrodeposited on the copper deposited in the first step. The overburden is made using a composition at pH 7 containing a sulfur salt of copper (II) ions and an organic salt of zinc (II) ions in the presence of ethylene diamine.

### A.—Materials and Equipment:

### Substrate:

The substrate used is the same as Example 3.

### Electrodeposition Solutions:

The two solutions used are the same as Example 4.

### Equipment:

The equipment used is the same as in Example 1.

### B.—Experimental Protocol:

It is the same as in Example 1.

### C—Results Obtained:

Transmission electron microscopy (TEM) analysis, carried out after annealing, reveals a flawless filling of holes on the walls of the trenches indicating good nucleation of the copper and no holes in the structures. The thick layer of copper on the structures is 300 nm. XPS analysis before annealing shows the presence of zinc on the order of 2 atomic percent uniformly in the alloy layer, while in structures copper is pure. This same type of analysis, after annealing, shows on the one hand the migration of zinc through the pure copper to reach the SiO₂-Cu interface and towards the extreme surface. Whereas, the Cu—NiB interface is intact with no trace of Zn in the NiB. On the other hand, the total contamination of oxygen, carbon and nitrogen does not exceed 600 atomic ppm. This solution has the advantage of creating copper lines of finer dimensions than in the prior art.

1. A process for fabricating a 3D-NAND flash memory, said process comprising the steps of
a) electrodepositing an alloy of copper and of a dopant metal selected from manganese and zinc by bringing a first surface of a metal layer into contact with an electrolyte comprising copper (II) ions and dopant metal ions, and then polarizing said first surface for a time sufficient to cover it with the copper-dopant metal alloy, and
b) annealing the alloy to cause it to separate and form a first layer of copper and a second layer comprising the dopant metal and/or an oxide thereof.

2. The process as claimed in claim 1, wherein the first layer of copper forms a copper bit line of the 3D-NAND flash memory.

3. The process as claimed in claim 1, wherein the electrolyte comprising copper (II) ions and dopant metal ions has a pH between 6.0 and 10.0.

4. The process as claimed in claim 1, wherein the metal layer comprises a second surface which is in contact with a mixed surface comprising both an insulating area and a conducting area, said insulating area being made of a dielectric material and said conducting area being made of a contact metal selected from tungsten, molybdenum, cobalt and ruthenium, said contact metal being intended to connect a copper bit line and a polysilicon channel of the 3D-NAND flash memory.

5. The process as claimed in claim 4, wherein during the step of annealing the alloy, the dopant metal migrates to the mixed surface, and in that the second layer comprising the dopant metal and/or an oxide thereof covers at least the insulating area of the mixed surface.

6. The process as claimed in claim 5, wherein the second layer comprises an oxide of the dopant metal and functions as a copper diffusion barrier.

7. The process as claimed in claim 4, wherein the metal layer is a metal seed layer selected from the group consisting of copper, a copper alloy, or tantalum, said seed layer having been deposited in contact with the mixed surface of an insulating area and a conducting area, in a step prior to the first electrodeposition step.

8. The process as claimed in claim 7, wherein a portion of the first surface of the metal seed layer is concave, defining a hollow delimited by the walls and bottom of a trench.

9. The process as claimed in claim 8, wherein the trench hollow has an average width at the opening ranging from 15 nm to 700 nm and an average depth ranging from 30 nm to 500 nm.

10. The process as claimed in claim 8, wherein the first step of electrodepositing the copper-dopant metal alloy is performed for a time sufficient to fill the hollow with said alloy.

11. The process as claimed in claim 1, wherein the metal layer is a trench-filling copper deposit, and the step of electrodepositing the copper-dopant metal alloy is performed for a time sufficient to cover the trench-filling copper deposit, in order to form an alloy deposit, the first copper layer formed as a result of the annealing step being subsequently polished in a third chemical-mechanical polishing step.

12. A 3D-NAND flash memory, wherein the 3D-NAND flash memory comprises a copper diffusion barrier material between a metal contact and a copper bit line the copper diffusion barrier material comprising zinc or manganese in order to suppress the intercalation of the copper diffusion barrier material, said barrier material being deposited by dry process and being selected from tantalum nitride and titanium nitride, said metal contact electrically connecting a polysilicon channel and said copper bit line in the 3D-NAND flash memory, and comprising a contact metal selected from tungsten, molybdenum, cobalt and ruthenium.

13. The process as claimed in claim 3, wherein the electrolyte comprising copper (II) ions and dopant metal ions has a pH between 6.5 and 7.5.
